(19) United States
(12) Patent Application Publication
(10) Pub. No.: US 2009/0001556 A1
(43) Pub. Date: Jan. 1, 2009

(54) LOW TEMPERATURE THERMAL INTERFACE MATERIALS

(76) Inventors: Haixiao Sun, Shanghai (CN); Daoqiang Lu, Chandler, AZ (US)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 11/771,872

(22) Filed: Jun. 29, 2007

(51) Int. Cl. H01L 23/373; H01L 21/58

(52) U.S. Cl. 257/712; 438/123; 257/E23.106; 257/E21.505

(57) ABSTRACT

A method may provide thermal interface material. The method comprises providing a first coating layer on a top side of a base metal layer and a second coating layer on a bottom side of the base metal layer, wherein the coating layer has a melting point lower than a melting point of the base metal layer; attaching the base metal layer to a die and a heat spreader; and melting the first coating layer and the second coating layer to bond to the die and the heat spreader.

### BACKGROUND

Indium solder is typically used as thermal interface material (TIM) for central processing unit (CPU) packages or any other packages that may use heat spreader. However, using Indium may increase the cost of the packages.

### BRIEF DESCRIPTION OF THE DRAWINGS

The invention described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIGS. 1 and 2 are schematic diagrams of a method that may be used to form a semiconductor package.

FIG. 3 is a schematic diagram of an embodiment of a semiconductor package that may be formed by the method of FIGS. 1 and 2.

### DETAILED DESCRIPTION

In the following detailed description, references are made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numbers refer to the same or similar functionality throughout the several views.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

The following description may include terms, such as upper, lower, top, bottom, first, second, etc. that are used for descriptive purposes only and are not to be construed as limiting.

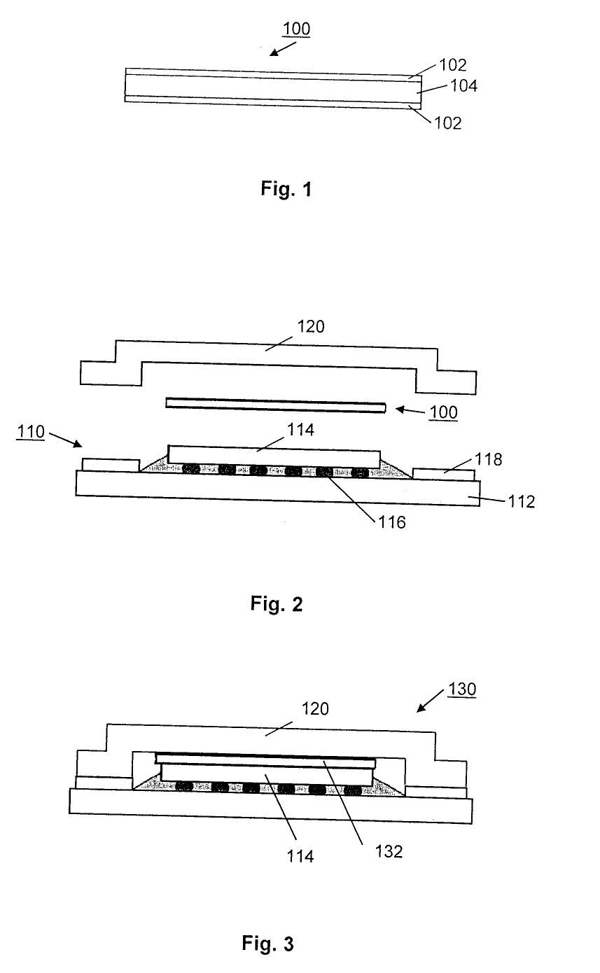

FIGS. 1 and 2 illustrate an exemplary embodiment of a method that may be used to form, e.g., a semiconductor package 130 of FIG. 3. Referring to FIG. 1, in one embodiment, a preform 100 may be provided. The solder preform 100 may comprise a base metal layer 104. In one embodiment, the base metal layer 104 may comprise a solder layer that may comprise Sn. For example, the base metal layer 104 may comprise SnPb, Sn and/or SnAg or the combination thereof. In another embodiment, any other metallic material that has a melting point higher than a temperature such as around 150° C. may be utilized. As shown in FIG. 1, one or both sides of the base metal layer 104 may be coated with a coating layer 102. In one embodiment, the coating layer 102 may comprise Bi, such as eutectic SnBi (e.g., 42Sn58Bi), eutectic SnBiAg (e.g., 42Sn57Bi1Ag), and/or Bi. In another embodiment, any other coating material may be utilized, such as that has a melting point lower than a melting point of the base metal layer 104 and may melt to bond to the heat spreader 120 and the die 114 at around the melting point of the coating material such as 140-180° C.

Referring to FIG. 2, an assembled package 110 may be provided. The package 110 may comprise a substrate 112. A die 114 may be bonded to the substrate 112, e.g., on the upper side thereof. As shown in FIG. 2, the die 114 may comprise a bump die that may comprise one or more bumps 116 to couple the die 114 to the substrate 112; however, in some embodiments, other interconnects may be utilized, including land grid arrays (LGA), ball grid arrays (BGA), etc. While FIG. 2 illustrates one die 114, some embodiments may comprise more dies 114 that have a different arrangement. Referring to FIG. 2, if the coating layer 102 comprises Bi only, no flux may be need for the coating layer 100. If the coating layer 102 utilizes other metal than Bi, such as eutectic SnBi and/or SnBiAg, a flux may be applied to the coating layer 102.

Referring to FIGS. 2 and 3, the preform 100 may be placed on the die 114, e.g., a back side (the top of FIG. 2) with no interconnect. A heat spreader 120 such as integrated heat spreader (IHS) may be attached to the assembled package 110 with the preform 100 interleaved between the die 114 and the heat spreader 120. In one embodiment, a sealant or adhesive 118, e.g., epoxy, silicone or any other adhesives, may be provided on the substrate 112 to secure the heat spreader 120 to the substrate 112. In one embodiment, if the coating layer 102 comprises eutectic SnBi or eutectic SnBiAg, with a temperature being ramped up to e.g., about 140-180° C., the coating layer 102 may melt to bond the heat spreader 120 and the die 114 and may form TIM bonding between the heat spreader 120 and the die 114. For example, the Bi component in the melt coating layer 102 may diffuse into the base metal layer 104, e.g., Sn matrix of the base metal layer 104 to form TIM 132. The TIM 132 may bond to the heat spreader 120 and the die 114, and may have a re-melting point higher than that of the eutectic SnBi or eutectic SnBiAg. In another embodiment, the sealant 118 may be cured around the temperature.

In another embodiment, if the coating layer 102 comprises a Bi layer, the Bi component in the coating layer 102 and Sn component in the base metal layer 104 may form eutectic phase (e.g., eutectic SnBi) with the temperature being ramped up to about 140-180° C. and the euctectic SnBi may then melt around the temperature to diffuse Bi component into the Sn matrix of the base metal layer 104, so as to form the TIM bonding. The obtained TIM 132 may have a melting point that is higher than that of the eutectic SnBi or SnBiAg.

While the methods of FIGS. 1 and 2 are illustrated to comprise a sequence of processes, the method in some embodiments may preform illustrated processes in a different order. Further, while the embodiments of FIGS. 1, 2 and 3 are illustrates to comprise a certain number of dies, interconnects, substrates, interconnects, chips, some embodiments may apply to a different number.

While certain features of the invention have been described with reference to embodiments, the description is not intended to be construed in a limiting sense. Various modifications of the embodiments, as well as other embodiments of the invention, which are apparent to persons skilled in the art to which the invention pertains are deemed to lie within the spirit and scope of the invention.

What is claimed is:

1. A method, comprising:
providing a first coating layer on a top side of a base metal layer and a second coating layer on a bottom side of the base metal layer, wherein the coating layer has a melting point lower than a melting point of the base metal layer;
attaching the base metal layer to a die and a heat spreader; and
melting the first coating layer and the second coating layer to bond to the die and the heat spreader.

2. The method of claim 1, wherein the base metal layer comprises Sn, and each of the first coating layer and the second coating layer comprises a Bi layer.

3. The method of claim 1, wherein the first coating layer and the second coating layer comprise one from a group comprising eutectic SnBi and eutectic SnBiAg.

4. The method of claim 1, wherein the first coating layer and the second coating layer comprise Bi.

5. The method of claim 3, comprising:
applying a flux to the first coating layer and the second coating layer, and diffusing Bi from the melt first coating layer and the melt second coating layer to form thermal interface for the die and the heat spreader.

6. The method of claim 2, comprising:
forming eutectic BiSn by Bi and Sn;
melting the eutectic BiSn; and
diffuse Bi into Sn matrix of the base metal layer to form thermal interface material for the die and the heat spreader.

7. The method of claim 1, wherein the base metal layer comprises one from a group comprising Sn, Ag and Pb.

8. A semiconductor package, comprising:
a based metal layer;
an upper coating layer and a lower coating layer on the base metal layer to form a thermal interface for a heat spreader and a semiconductor die,
wherein each coating layer having a melting point lower than that of the base metal layer.

9. The semiconductor package of claim 8, wherein the base metal layer comprises Sn, and each coating layer comprises Bi.

10. The semiconductor package of claim 8, wherein each coating layer comprises one from a group comprising eutectic SnBi, and eutectic SnBiAg.

11. The semiconductor package of claim 8, wherein each coating layer comprises Bi.

12. The semiconductor package of claim 8, wherein the base metal layer comprises one from a group comprising Sn, Ag and Pb.

13. The semiconductor package of claim 8, wherein each coating layer comprises Bi that is to diffuse into an Sn matrix of the base metal layer.

14. The semiconductor package of claim 8, wherein each coating layer comprises Bi and the base metal layer comprises Sn to form eutectic SnBi, wherein the eutectic SnBi is to diffuse Bi component into the Sn matrix of the base metal layer.
